(19) United States
(12) Patent Application Publication
(10) Pub. No.: US 2009/0280050 A1
(43) Pub. Date: Nov. 12, 2009

(54) Apparatus and Methods for Casting Multi-Crystalline Silicon Ingots

(75) Inventors: Kramadhati V. Ravi, Atherton, CA (US); Hans J. Walitzki, Portland, OR (US)

Correspondence Address: DIEHL SERVILLA LLC, 77 BRANT AVENUE, SUITE 210, CLARK, NJ, 07066, US

(73) Assignee: Applied Materials, Inc., Santa Clara, CA (US)

(21) Appl. No.: 12/428,535

(22) Filed: Apr. 23, 2009

Related U.S. Application Data
(60) Provisional application No. 61/047,939, filed on Apr. 25, 2008.

(51) Int. Cl. C01B 33/02; B01D 9/00; C30B 28/00

(52) U.S. Cl. 423/349; 422/245.1; 422/109

(57) ABSTRACT

Apparatuses and methods for making a multi-crystalline silicon ingot by directional solidification comprising two or more moveable heat shields located beneath the crucible, the heat shields being opened in a controlled manner to remove heat and produce a high quality silicon ingot.

### CROSS REFERENCE TO RELATED APPLICATION

This application claims the benefit of priority under 35 U.S.C. § 119(e) to U.S. Patent Application No. 61/047,939, filed Apr. 25, 2008, which is hereby incorporated by reference in its entirety.

### TECHNICAL FIELD

Embodiments of the present invention generally relate to methods and associated apparatuses for the preparation of multi-crystalline silicon ingots. More specifically, embodiments of the present invention relate to apparatuses and methods for the directional solidification of multi-crystalline silicon ingots having fewer crystal defects than conventional methods.

### BACKGROUND

Alternative power sources have been studied with greater interest as a result of the sharp rise in oil and gasoline prices. Solar power is one of the promising technologies for generating clean, renewable electricity. Solar cells, also called photovoltaic cells, are devices which convert solar energy into electricity. These cells have evolved significantly over the past two decades, with experimental efficiencies increasing from less than about 5% in 1980 to almost 40% in 2008.

In the early development of solar cells, single-crystal or semi-conductor grade silicon was employed. However, crystalline silicon ingots of this type are expensive due to the cost associated with creating the crystalline structure. One of the traditional methods of creating a single crystal of silicon is by the Czochralski process. In this process, polysilicon is melted in a cylindrical crucible. The melt can be doped to create n-type or p-type silicon. A seed crystal is introduced to the melt causing crystal growth. The crystal is pulled from the melt, creating a cylindrical single crystal ingot. Single-crystal silicon wafers, less than about 300 μm thick, are then cut from this cylindrical ingot.

However, it is now known that single-crystal silicon is not required for producing efficient solar cells. Multi-crystalline, also referred to as multi-crystalline, silicon ingots can be created using the directional solidification process, sometimes called the oriented solidification process. Directional solidification employs a rectangular-shaped crucible, often heated from the sides and bottom. Generally, the crucible is filled with polysilicon and melted in an inert atmosphere. Once melted, the crucible is allowed to cool in a controlled manner from the bottom up. Heat loss during cooling occurs at the sides of the crucible by vertically moving graphite heat shields, to allow radiative heat loss from the crucible and the silicon.

Upon cooling, nucleation occurs, resulting in crystal growth upward from the bottom of the crucible. The ingot produced is rectangular in shape, as opposed to the cylindrically shaped ingot from the Czochralski process. The directional solidification process causes any impurities in the silicon to be pushed to the top of the crucible where they concentrate in the top layer of the ingot. This layer is subsequently cut from the ingot, leaving substantially pure multi-crystalline silicon.

Today, the majority of solar cells are manufactured using crystalline silicon wafers. Over 50% of crystalline silicon solar cells are manufactured using multicrystalline silicon wafers which are manufactured by directional solidification. However, there are several undesirable aspects to the current process: excessive power consumption and the interface is always concave resulting in higher defect density in the resulting ingot. To remove these defects, the sides of the rectangular ingot must be ground off, resulting in loss of about 1 cm of the outer silicon surface. Therefore, there is a continuing need in the art for methods and apparatus to create multi-crystalline silicon ingots with lower defect density.

### SUMMARY

Aspects of this invention involve the use of horizontally moving heat shields at the bottom of the crucible in directional solidification process and apparatus. This allows for controlled heat loss from the bottom of the crucible, resulting in controlled growth of crystals and a convex interface between the solid and liquid silicon during solidification as compared to a concave interface in the prior art. This design also results in a flatter crystallization interface, lower defect density, less stress and fewer defects in the ingot center as compared to current state of the art. This invention also enables faster crystallization rates while maintaining a desirable interface shape (no bending at edges and an overall convex shape). Furthermore the total heat loss through the movable bottom heat shields will be lower than the heat loss during crystallization as compared to prior art.

One or more embodiments of the invention are directed to an apparatus for producing multi-crystalline silicon ingots by directional solidification. The apparatus comprises a crucible having four sides and a bottom. The top of the crucible can be open or closed depending upon the specific application. The crucible is placed within a crucible holder. A plurality of heaters surrounds at least a portion of the crucible holder. The heaters are capable of causing silicon within the crucible to melt. At least two moveable heat shields below the crucible holder are adapted to move in the same plane as the crucible bottom. The moveable heat shields can be made of any suitable material, such as graphite, graphite felt or other graphite insulation, but is not limited to graphitic materials and may also be made of suitable metals, such as molybdenum, acting as heat reflector.

The heaters of some embodiments are located adjacent the four sides of the crucible holder. In other embodiments a heater is located above the crucible. In still further embodiments a heater is located below the crucible. A cooler located below the crucible may also be present. A water cooled jacket surrounding the apparatus may also be employed.

The moveable heat shields according to one or more embodiments comprises four members adapted to move so that an opening having a similar shape to the crucible bottom is formed. The members of some embodiments can move independently of each other. A specific embodiment has two movable, partially overlapping shields. Another embodiment involves two rotating overlapping shields.

In other embodiments, one or more temperature probes are disposed within the apparatus. A control mechanism for monitoring the temperature probes may be present. The control mechanism may also be able to adjust the location of, and the extent of movement of, individual moveable heat shields to controllably extract heat from the molten silicon in the crucible.

Additional embodiments of the invention are directed to methods of producing multi-crystalline silicon ingots by directional solidification. The methods comprise the transferring of silicon into a crucible located within a furnace. The crucible may have a bottom and four sides. A top for the crucible may also be present. The crucible is held within a crucible holder. The crucible is heated with heating elements located adjacent the crucible holder sides. The crucible is surrounded at least on the bottom with a moveable heat shield. The silicon within the crucible melted and then cooled in a controlled manner to achieve controlled solidification of the silicon by moving the heat shields. A multicrystalline silicon ingot is produced where the grain size in the center of the ingot is substantially uniform with respect to the grain size at the edge of the ingot.

In other embodiments, the heat shield comprises four members adapted to move so that an opening having a similar shape to the crucible bottom can be formed.

Further embodiments of the invention are directed to multi-crystalline silicon ingots. The ingots comprise four sides and a solid-liquid silicon interface during solidification. The solid-liquid interface is controlled by moving the heat shields. The multi-crystalline silicon ingot of some embodiments has an interface which curls downward at the intersection of the solid-liquid interface with the walls of the crucible. The multi-crystalline silicon ingot of other embodiments has an interface which is perpendicular to the ingot side. The multi-crystalline silicon ingot of further embodiments shows uniform grain size from the center of the ingot to the edges of the ingot.

### BRIEF DESCRIPTION OF THE DRAWINGS

FIG. 1 shows a schematic of a directional solidification chamber according to one or more embodiments of the invention;

FIGS. 2A-2D show positioning of moveable heat shields according to one or more embodiments;

FIGS. 3A-3C show additional embodiments of movable heat shields;

FIG. 4 shows the shape of a solid-liquid silicon interface achieved using methods and apparatus according to the prior art; and

FIGS. 5A-5B show the shape of solid-liquid silicon interfaces achieved using methods and apparatus according to embodiments of the invention.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

As used in this specification and the appended claims, the singular forms “a”, “an” and “the” include plural referents unless the context clearly indicates otherwise. Thus, for example, reference to “an ingot” includes a combination of two or more ingots, and the like.

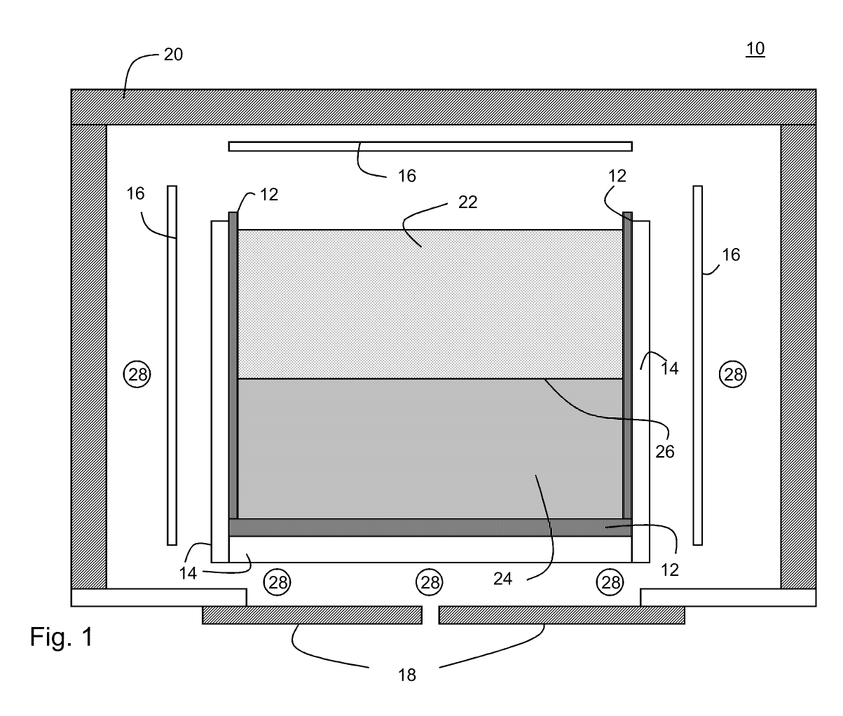

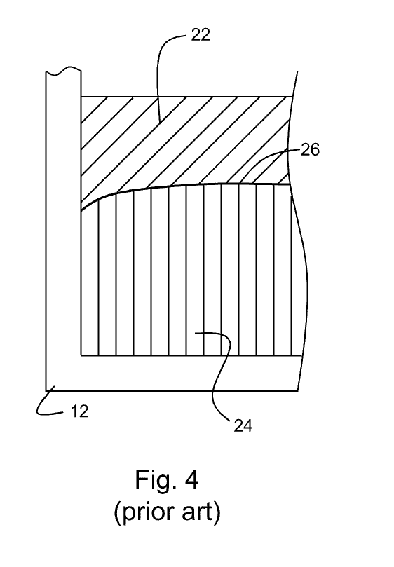

Referring to FIG. 1, a schematic representation of a directional solidification chamber 10 according to one or more embodiments of the invention is shown. Crucible 12 is supported within crucible holder 14 which is located within a graphite enclosure 20. Silicon within the crucible 12 is melted with heat generated by heaters 16. Once melted, the moveable heat shields 18 are opened in a direction parallel to the crucible 12 bottom. The heat shields 18 are opened in a controlled manner to remove heat from the chamber 10. The liquid silicon 22 cools to a solid mass 24 in the bottom of the crucible. An interface 26 between the liquid silicon 22 and the solid silicon 24 is formed. The shape of this interface 26 is indicative of the quality of the resultant ingot, as discussed below with reference to FIG. 4.

In one or more embodiments, the heat shields 18 are opened by a control mechanism (not shown). The control mechanism can be a simple control mechanism such as a handle and/or track that allows the heat shields 18 to be opened and closed manually. In certain embodiments, the control mechanism may include an automated mechanism such as a motor or other suitable device to control the extent of opening of the heat shields 18. In a specific embodiment, the control mechanism is in communication with a sensor that can measure the temperature within the chamber 10 using strategically placed temperature probes 28 throughout the chamber 10. Suitable temperature probes may include thermocouples or pyrometers. By evaluating the temperature profile at various locations within the chamber 10, the control mechanism can open any one or all of the heat shields 18. This could be achieved by utilizing a microprocessor or computer using a feedback control system that would adjust the extent of opening of the heat shields based upon the temperature readings from the temperature probes 28. This can allow for a uniform temperature to be maintained across the bottom of the crucible 12, resulting in a uniform ingot.

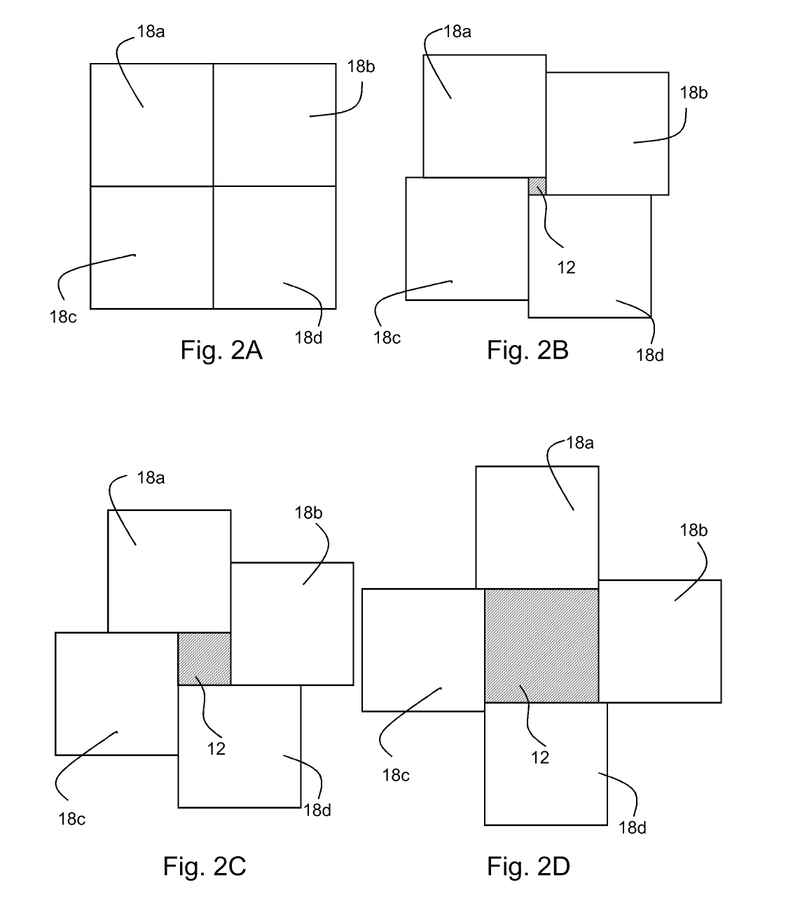

FIGS. 2A-2D show exemplary configurations for the moveable heat shields 18a-18d of one or more embodiments of the invention. During the melting stage, the heat shields 18a-18d are closed, as shown in FIG. 2A, to retain as much heat within the chamber 10 as possible. Upon cooling, the heat shields 18a-18d are opened to varying extents, as shown in FIGS. 2B-2D, to allow heat to escape from the chamber 10. The crucible bottom 12 is shown in the center of the heat shields 18a-18d in FIGS. 2B-2D. As referenced above, the degree or extent of opening of the heat shield 18a-18d could be controlled by a computer or microprocessor in communication with temperature probes. Experimental data could be utilized to determine the optimum temperature and extent or degree of opening of the heat shields 18a-18d to optimize the rate and extent of opening of the heat shields during cooling of silicon in the crucible during ingot formation.

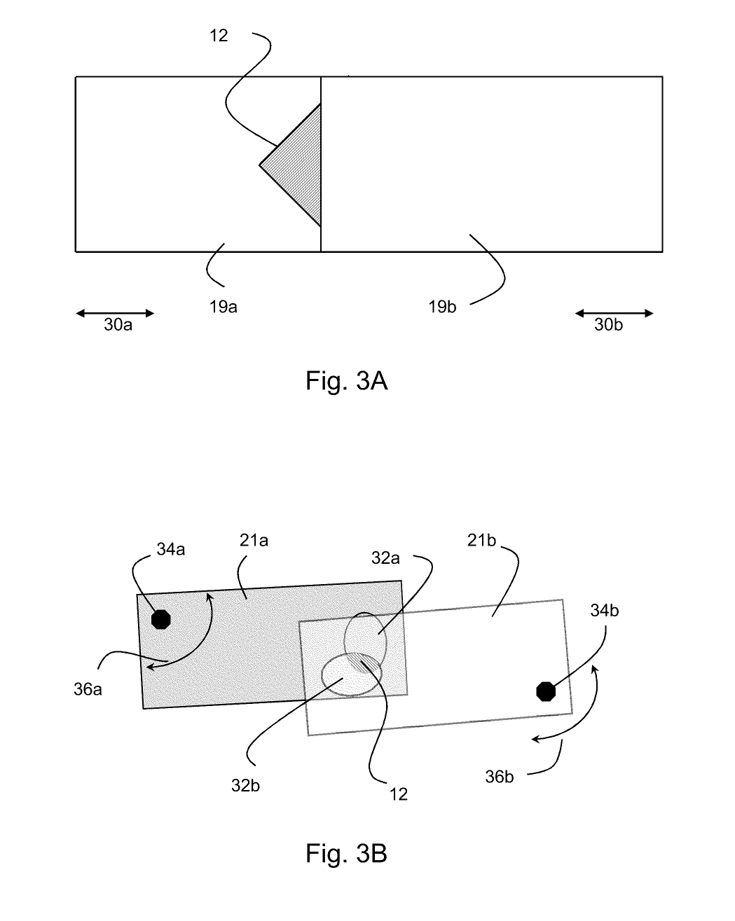

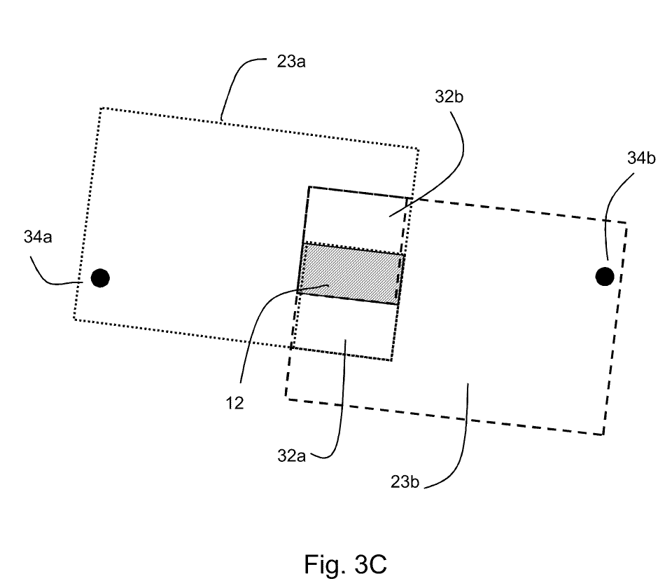

FIG. 3A shows a detailed embodiment of the invention. Moveable heat shields 19a and 19b overlap. The bottom shield 19a is show with a triangular shaped cutout, but this could be any desired shape. The top shield 18a is shown as a single piece, but does not need to be. Shields 19a, 19b can be moved in the direction indicated by arrows 30a and 30b. Upon increasing the distance between shields 19a, 19b, the cutout in the bottom shield 18a is revealed, thus revealing the bottom of the crucible 12, and allowing for the controlled cooling of the crucible.

FIG. 3B shows another detailed embodiment. Here, the moveable heat shields 21a and 21b overlap with each shield having an oval shaped cutout 32a and 32b. Shields 21a and 21b rotate in or out, depending on the need, along path defined by the arrows 36a and 36b. The shields 21a, 21b are fixed at pivot points 34a and 34b. When the shields 21a, 21b are pivoted such that the cutouts 32 overlap, an opening in the shields 21a, 21b is created, thereby revealing the crucible 12 and allowing for the controlled cooling of the crucible.

FIG. 3C shows a similar detailed embodiment as that of FIG. 3B. Here the moveable shields 23a and 23b pivot in points 34a and 34b, respectively. Rectangular shaped cutouts 32a and 32b overlap, creating an opening in the shields 23a, 23b and revealing the crucible 12. This allows for the controlled cooling of the crucible.

The shape of the interface 26 is correlated to the quality of the ingot produced. FIG. 4 shows the shape of the interface 26 obtained with traditional dimensional solidification devices. It can be seen that the interface 26 between the solid silicon 24 and the liquid silicon 22 curves downward where it meets the crucible wall 12. This region of curvature results in an ingot with different grain sizes near the edges than in the center. These edges must be ground away to reveal uniform silicon, resulting in a loss of about 1 cm of the silicon.

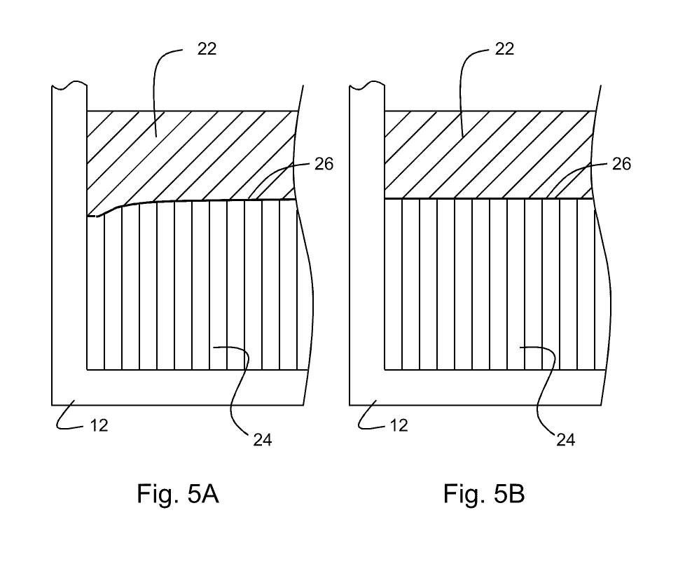

The interface 26 achieved according to embodiments of the present invention can be seen in FIGS. 5A and 5B. FIG. 5A shows an interface 26 that curves downward but is flat at the edges. FIG. 5B shows an interface 26 that is substantially flat across the entire liquid 22—solid 24 junction. Both of these interfaces 26 will result in an ingot with substantially equal grain sizes across the cross-section of the ingot, eliminating or greatly reducing the need to grind off the exterior of the ingot.

Crucibles for use with embodiments of the invention are generally rectangular in shape, having four sides and a bottom. The crucible can be made of any material suitable to contain liquid silicon without causing contamination (e.g., quartz with a silicon nitride coating). High purity quartz is presently a preferred material for the production of silicon ingots. The crucible holder can be made of any material suitable for holding the crucible (e.g., graphite).

Accordingly, one or more embodiments of the invention are directed to an apparatus for producing multi-crystalline silicon ingots by directional solidification. The apparatus comprises a crucible having four sides and a bottom. The top of the crucible can be open or closed depending upon the specific application. The crucible is placed within a crucible holder. A plurality of heaters surround at least a portion of the crucible holder. The heaters are capable of causing silicon within the crucible to melt. At least two moveable heat shields below the crucible holder are adapted to move in the same plane as the crucible bottom. The moveable heat shields can be made of any suitable material, such as graphite, graphite felt or other graphite insulation, but is not limited to graphitic materials.

The heaters of some embodiments are located adjacent the four sides of the crucible holder. In other embodiments, a heater is located above the crucible. In still further embodiments a heater is located below the crucible. A cooler located below the crucible may be present. A water cooled jacket surrounding the apparatus may also be employed.

The moveable heat shields of one or more embodiments comprise up to four members adapted to move so that an opening having a similar shape to the crucible bottom is formed. The members of some embodiments can move independently of each other. Other embodiments include two linear movable shields which overlap when closed (FIG. 3A); two rotating heat shields (FIGS. 3B and 3C)

In other embodiments, one or more temperature probes are disposed within the apparatus. A control mechanism for monitoring the temperature probes may be present. The control mechanism may also be able to adjust the location of individual moveable heat shields to controllably extract heat from the molten silicon in the crucible.

Additional embodiments of the invention are directed to methods of producing multi-crystalline silicon ingots by directional solidification. The methods comprise the transferring of silicon into a crucible located within a furnace. The crucible may have a bottom and four sides. A top for the crucible may also be present. The crucible is held within a crucible holder. The crucible is heated with heating elements located adjacent the crucible holder sides. The crucible is surrounded at least on the bottom with a moveable heat shield. The silicon within the crucible melted and then cooled in a controlled manner to achieve controlled solidification of the silicon by moving the heat shields. A multicrystalline silicon ingot is produced where the grain size in the center of the ingot is substantially uniform with respect to the grain size at the edge of the ingot.

In other embodiments, the heat shield comprises four members adapted to move so that an opening having a similar shape to the crucible bottom can be formed. It will be understood that the configuration of four shields shown in FIGS. 2A-2B is exemplary only. Accordingly, fewer or greater than four movable shields may be utilized in accordance with alternative embodiments. For example, two opposing shields could be utilized. Other variants, such as those shown in FIG. 3) are within the scope of the invention.

Further embodiments of the invention are directed to multi-crystalline silicon ingots. The ingots comprise four sides and a solid-liquid silicon interface during solidification. The solid-liquid interface is controlled by moving the heat shields. The multi-crystalline silicon ingot of some embodiments has an interface which curls downward at the intersection of the solid-liquid interface with the walls of the crucible. The multi-crystalline silicon ingot of other embodiments has an interface which is perpendicular to the ingot side. The multi-crystalline silicon ingot of further embodiments shows uniform grain size from the center of the ingot to the edges of the ingot.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. An apparatus for producing multi-crystalline silicon ingots by directional solidification, the apparatus comprising:
a crucible including a side wall and a bottom;
a crucible holder including a side wall and a bottom portion for holding the crucible;
a plurality of fixed heaters surrounding at least a portion of the crucible holder, the heaters capable of heating silicon to melting temperature; and
at least two moveable heat shields at the bottom portion of the crucible holder, the heat shields moveable in the same plane as the crucible bottom to control.

2. The apparatus of claim 1, wherein heaters are located adjacent the side wall of the crucible holder

3. The apparatus of claim 1, wherein one or more heat spreaders are disposed between the heater and the crucible holder side walls.

4. The apparatus of claim 1, further comprising a heater located above the crucible.

5. The apparatus of claim 1, further comprising a heater located below the crucible.

6. The apparatus of claim 1, wherein the moveable heat shield comprises graphite insulation.

7. The apparatus of claim 1, further comprising a cooler located below the crucible.

8. The apparatus of claim 1, wherein the crucible bottom comprises four members arranged to form an opening having a similar shape to the crucible.

9. The apparatus of claim 1, further comprising a temperature probe for monitoring the temperature, the temperature probe in communication with a control mechanism for adjusting the position of the moveable heat shields to control the rate of heat extracted from the molten silicon in the crucible.

10. The apparatus of claim 1, further comprising a water cooled jacket around the apparatus.

11. The apparatus of claim 1, wherein each moveable heat shield is adapted to move independently of the other heat shields.

12. The apparatus of claim 1, wherein the crucible and the crucible holder include four side walls.

13. The apparatus of claim 12, wherein the ingot comprises four sides and a solid-liquid silicon interface during solidification which is controlled by the moveable heat shield and the interface curls downward at the intersection of the solid-liquid interface with the walls of the crucible.

14. The apparatus of claim 12, wherein the interface produced by the apparatus is perpendicular to the ingot side.

15. The apparatus of claim 12, wherein the ingot produced by the apparatus exhibits uniform grain size from the center of the ingot to the edges of the ingot.

16. A method of producing a multi-crystalline silicon ingot by directional solidification, the method comprising:
transferring silicon into a crucible located within a furnace, the crucible comprising a bottom a side wall and contained within a crucible holder;
heating the crucible with heating elements located adjacent the crucible holder side wall;
surrounding the crucible on at least the crucible bottom with a moveable heat shield;
melting the silicon in the crucible; and
cooling the melted silicon in the crucible in a controlled manner to achieve controlled solidification by changing the position of the heat shield with respect to the crucible bottom.

17. The method of claim 16, wherein the crucible includes four side walls and the crucible bottom comprises four members adapted to move so that an opening having a similar shape to the crucible bottom can be formed.

18. The method of claim 16, wherein a multi-crystalline silicon ingot is produced where the grain size in the center of the ingot is substantially uniform with the grain size at the edge of the ingot.

19. A multi-crystalline silicon ingot made prepared using the apparatus of claim 16, the ingot having a top surface, four sides, and an interface being defined as the solid-liquid interface.

20. The multi-crystalline silicon ingot of claim 19, wherein the interface curls downward at the intersection of the solid-liquid interface with the walls of the crucible.

21. The multi-crystalline silicon ingot of claim 19, wherein the interface is perpendicular to the ingot side.
